(19) United States
(12) Patent Application Publication
(10) Pub. No.: US 2014/0170862 A1
(43) Pub. Date: Jun. 19, 2014

(54) SUBSTRATE PROCESSING APPARATUS, SUBSTRATE PROCESSING METHOD AND NON-TRANSITORY STORAGE MEDIUM

(71) Applicant: Tokyo Electron Limited, Tokyo (JP)

(72) Inventor: Yoshinori TOYODA, Nirasaki City (JP)

(73) Assignee: Tokyo Electron Limited, Tokyo (JP)

(21) Appl. No.: 14/089,136

(22) Filed: Nov. 25, 2013

(30) Foreign Application Priority Data
Dec. 13, 2012 (JP) 2012-272514

(51) Int. Cl. H01L 21/263; H01L 21/67; H01L 21/677; H01L 21/02

(52) U.S. Cl. CPC H01L 21/2636; H01L 21/02667; H01L 21/67115; H01L 21/67748; H01L 21/67766
USPC 438/795; 432/56; 432/77; 432/244

(57) ABSTRACT

A substrate processing apparatus includes a substrate holding part configured to hold and support a substrate, a heating module configured to heat a substrate, and a cooling module configured to cool the substrate heated in the heating module. The substrate processing apparatus further includes a substrate transfer mechanism configured to take out the substrate from the substrate holding part and to sequentially transfer the substrate to the heating module and the cooling module, and a control unit configured to set a cooling time of the substrate in the cooling module based on a transfer history of the substrate while the substrate heated in the heating module is loaded into the cooling module.

### CROSS-REFERENCE TO RELATED APPLICATION

This application claims the benefit of Japanese Patent Application No. 2012-272514, filed on Dec. 13, 2012, in the Japan Patent Office, the disclosure of which is incorporated herein in its entirety by reference.

### TECHNICAL FIELD

The present disclosure relates to a substrate processing apparatus, a substrate processing method and a non-transitory storage medium for cooling a substrate subjected to heating processing.

### BACKGROUND

In a process of manufacturing semiconductor devices, there is a process of single-crystallizing a surface of a silicon film polymerized on a semiconductor wafer (hereinafter, referred to as a wafer) by irradiating the silicon film with, for example, a microwave, for heating thereof to activate doping atoms. The wafer after the heating process has a temperature of, for example, 400 degrees C. or so, but since a carrier is made of resin and this temperature exceeds a heatproof temperature of the carrier, the wafer cannot be loaded into the carrier as it is. Therefore, it is necessary for the wafer on which the heating processing is performed to be cooled below the heatproof temperature of the carrier by a cooling module before the wafer is loaded into the carrier.

Here, when a plurality of wafers is consecutively processed, in a heating module or a cooling module, a wafer exchange operation is performed. During the wafer exchange operation, for example, an unprocessed wafer is held and supported to be carried into the module, until the processed wafer is taken out from the module, and the unprocessed wafer is loaded when the processed wafer is carried out from the module. However, according to a sequence of transferred wafers or a use status of each module, the exchange operation may or may not be the same for all wafers. For this reason, in some cases, a transfer time of a wafer transferring to the cooling module from the end of the heating processing may be different for each wafer. As such, a cooling time of all wafers is set based on a case in which the transfer time of a wafer is the shortest, i.e., a temperature of a wafer is highest when loaded into the cooling module. However, when the transfer time for a wafer is long and the wafer is already sufficiently cooled, the wafer continues to be excessively cooled in the cooling module according to the set cooling time. Such excessive cooling causes throughput deterioration.

In related art, a technique of preventing throughput deterioration is described. The throughput deterioration is prevented by changing a transfer schedule based on the number of used modules set by a user in a substrate processing apparatus having a plurality of modules performing the same processing. However, even in this case, there may be a waiting time for loading into a module according to a setting time of processing in a module, whereby some cases of throughput deterioration may occur.

### SUMMARY

Some embodiments disclosed in the present disclosure are made in consideration of the above circumstances and provides a technique of improving throughput by suppressing continuous, excessive cooling in a cooling module when a substrate is heated and then cooled.

According to some aspects of the present disclosure, provided is a substrate processing apparatus, including: a substrate holding part configured to hold and support a substrate; a heating module configured to heat a substrate; a cooling module configured to cool the substrate heated in the heating module; a substrate transfer mechanism configured to take out the substrate from the substrate holding part and to transfer the substrate to the heating module and the cooling module in order; and a control unit configured to set a cooling time of the substrate in the cooling module based on a transfer history of the substrate while the substrate heated in the heating module is loaded into the cooling module.

According to some other aspects of the present disclosure, provided is a method of processing a substrate, including: loading a substrate from a substrate holding part to a heating module by a substrate transfer mechanism; unloading the heated substrate from the heating module and loading it to a cooling module by the substrate transfer mechanism; setting a cooling time of the substrate in the cooling module based on a transfer history of the substrate while the substrate heated in the heating module is loaded into the cooling module; and unloading the substrate from the cooling module after the cooling time elapses in the cooling module.

According to some still other aspects of the present disclosure, provided is a non-transitory storage medium storing a computer program used in a substrate processing apparatus including a heating module configured to heat a substrate, a cooling module configured to cool a substrate, and a substrate transfer mechanism. The computer program includes a group of steps for performing the method according to the above-described aspects.

### BRIEF DESCRIPTION OF THE DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a plan view showing a substrate processing apparatus according to an embodiment of the present disclosure;

FIG. 2 is a sectional view showing a configuration of a heating module according to the embodiment of the present disclosure;

FIG. 3 is a sectional view showing a configuration of a cooling module according to the embodiment of the present disclosure;

FIG. 4 is a view illustrating a configuration of a control unit according to the embodiment of the present disclosure;

FIG. 5 is a flowchart illustrating a process of determining a cooling time in the cooling module;

FIG. 6 is a flowchart illustrating the process of determining the cooling time in the cooling module;

FIGS. 7A to 7C are views illustrating a first process of processing substrates;

FIGS. 8A to 8C are views illustrating the first process of processing substrates;

FIGS. 9A to 9C are views illustrating the first process of processing substrates;

FIGS. 10A and 10B are views illustrating the first process of processing substrates;

FIG. 11 is a plan view showing a substrate processing apparatus according to a second embodiment; and

FIG. 12 is a characteristic diagram showing a cooling time of a substrate according to examples.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

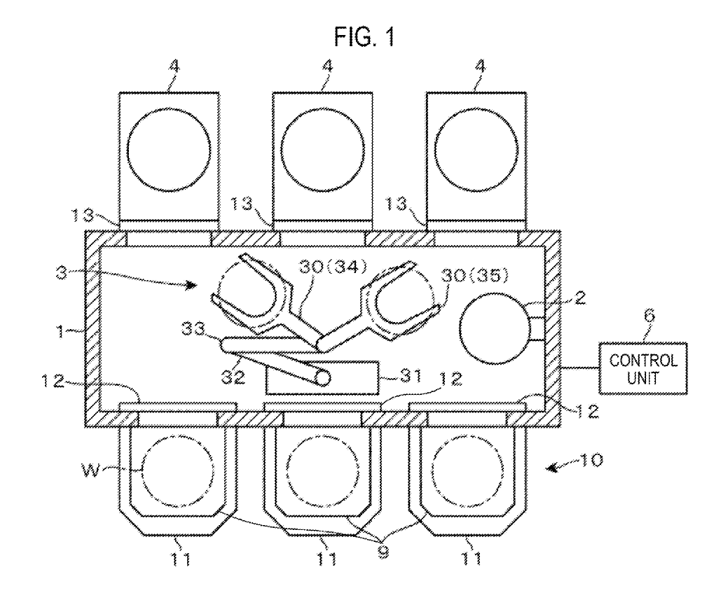

As shown in FIG. 1, a substrate processing apparatus according to a first embodiment is provided with an atmospheric transfer chamber 1 having a rectangular shape in the top view. A loading and unloading port 10, which is a container mounting part for loading and unloading wafers W, is installed in one of the long sides of the atmospheric transfer chamber 1. The loading and unloading port 10 includes a plurality of loading and unloading stages 11, and doors 12 installed in the respective loading and unloading stages 11. Each of the loading and unloading stages 11 is mounted with a carrier 9 that is a substrate holding part capable of accommodating a plurality of wafer W. For example, three heating modules 4 are connected to the other long side of the atmospheric transfer chamber 1 through gates 13, respectively. A cooling module 2, which will be described later, is installed at one end of the short sides inside the atmospheric transfer chamber 1.

Since wafers W are transferred between the heating modules 4, the cooling module 2 and the loading and unloading port 10, a transfer arm 3, a substrate transfer mechanism, is installed in the atmospheric transfer chamber 1. The transfer arm 3 is installed in an order of a lower arm portion 32 and an upper arm portion 33 on a fixed portion 31 that is fixed to a bottom surface of the atmospheric transfer chamber 1. Two substrate holding members 30 horizontally unfolded are coaxially installed to be individually pivotable at the distal end of the upper arm portion 33. The lower arm portion 32 and the upper arm portion 33 are constituted as a SCARA type multi joint arm connected through a rotational shaft not shown. In addition, the entire multi-joint arm is pivoted or extended and retracted by rotating a pivoting shaft in the lower arm portion 32 or the main body of the lower arm portion 32 by means of a motor for extension and retraction (not shown) and a motor for pivoting (not shown) installed in the fixed portion 31. Further, the respective substrate holding members 30 may be configured to be individually pivotable. In addition, a pivoting shaft of the lower arm portion 32 and fixed portion 31 may be configured to be lifted up and down by a lifting mechanism (not shown) and to adjust a level of the substrate holding members 30.

When a joint side of the two substrate holding members 30 is joined to the upper arm portion 33, which is referred to as a proximal end, the two substrate holding members 30 are formed in the shape of forks, which are branched off and forwarded from the proximal end toward left and right distal ends, respectively. One of the two substrate holding members 30 is a low temperature holding member 34 for transferring a low temperature wafer W, and the other substrate holding member is a high temperature holding member 35 made of a heat resisting material for mostly transferring a high temperature wafer W.

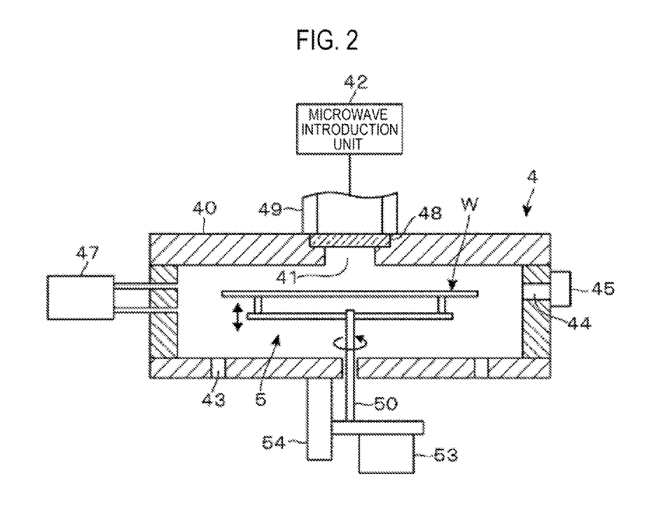

As shown in FIG. 2, the heating module 4 is configured as a microwave heating processing unit, which heats, for example, a wafer W for manufacturing semiconductor devices, by irradiating it with a microwave to single-crystallize a silicon film polymerized on a surface of the wafer. A flat cylinder-shaped processing container 40 is made of, for example, stainless steel, and has an inner wall surface which is mirror-finished. For example, a microwave introduction unit 42 having a magnetron connected to a high voltage power supply is connected to a ceiling of the processing container 40 through a wave guide 49. In addition, reference numeral 48 designates a light transmissive window, reference numeral 43 designates an exhaust port, reference numeral 45 designates a gate, and reference numeral 44 designates a carrying in/out hole. In addition, a gas supply mechanism 47 is connected to a lateral side of the processing container 40. The interior of the processing container 40 is provided with a supporting part 5 for holding and supporting a wafer W in a horizontal position, and the supporting part 5 is supported by a support pillar 50, which passes through the bottom surface of the processing container 40. The support pillar 50 is configured to be rotatable about the vertical axis by a rotation driving part 53. In addition, a lifting mechanism 54 is installed in combination with the support pillar 50, which is accordingly configured to be lifted and lowered. The heating module 4 heats the wafer W supported by the supporting part 5 by irradiating the wafer W with a microwave from an upper portion, for example, for 120 seconds, and the wafer W after the completion of the heating processing has an edge temperature of 400 degrees C. or so when the wafer W is transferred by the transfer arm 3.

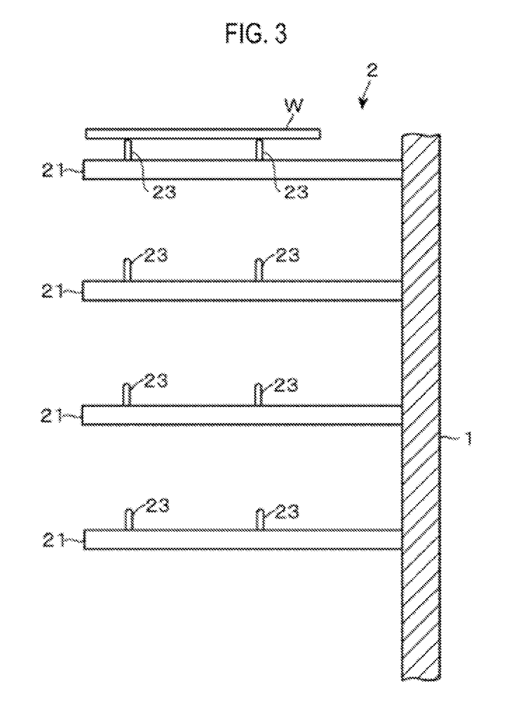

As shown in FIG. 3, the cooling module 2 includes cooling stages 21, which are vertically arranged in a multiple-stage, for example, four stages. Each of the cooling stages 21 has three support pins 23, and a wafer W is transferred to the support pins 23 by the lifting operation of the above-described transfer arm 3, thereby being supported in a horizontal position.

The operation of the cooling module 2 will be described. When the heating processing on the wafer W is completed, the wafer W is transferred by the transfer arm 3 and delivered to the support pins 23. The wafer W is supported in the horizontal position by the support pins 23 under the normal atmosphere, so that heat radiation progresses from the surface of the wafer W to cool the wafer W. The wafer W is cooled, for example, for 180 seconds, until a temperature at an edge of the wafer W is 80 degrees C. or so.

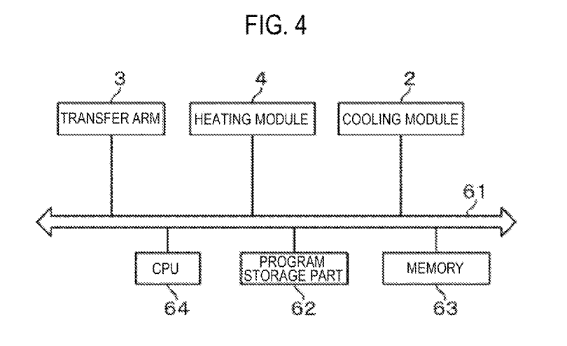

The substrate processing apparatus includes a control unit 6 (see FIG. 1). The control unit 6 includes, for example, a computer, and as shown in FIG. 4, a program storage part 62, a memory 63 and a CPU 64 are connected via a bus 61. The program storage part 62 stores a program including a group of steps for performing a series of operations including the operation of the transfer arm 3. In one embodiment, just before a wafer W is loaded into the cooling module 2, a cooling time of the cooling module 2 for the wafer W is set based on a transfer history of the wafer W. A cooling time is previously stored in the memory 63, for example, in association with each transfer history, and a cooling time according to a transfer history of a wafer W is set by being read from the memory by a program. In on embodiment, the transfer history is recognized as four transfer histories P1 to P4, and a cooling time is assigned to each of the transfer histories P1 to P4.

P1: No exchange in heating module, No exchange in cooling module—Cooling time T1 (for example, 180 seconds)

P2: Exchange in heating module, No exchange in cooling module—Cooling time T2 (for example, 175 seconds)

P3: No exchange in heating module, Exchange in cooling module—Cooling time T3 (for example, 175 seconds)

P4: Exchange in heating module, Exchange in cooling module—Cooling time T4 (for example, 170 seconds)

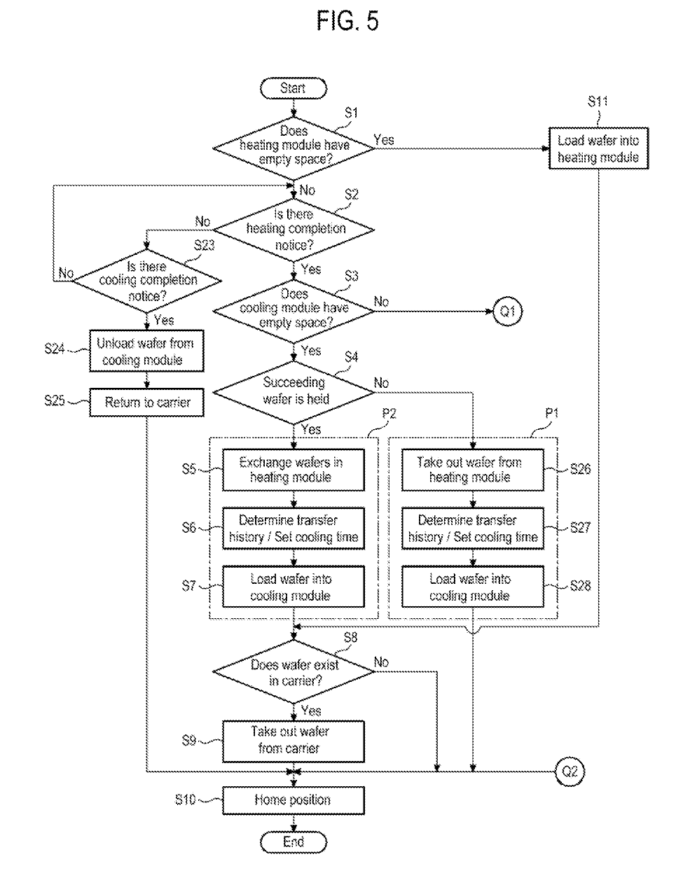

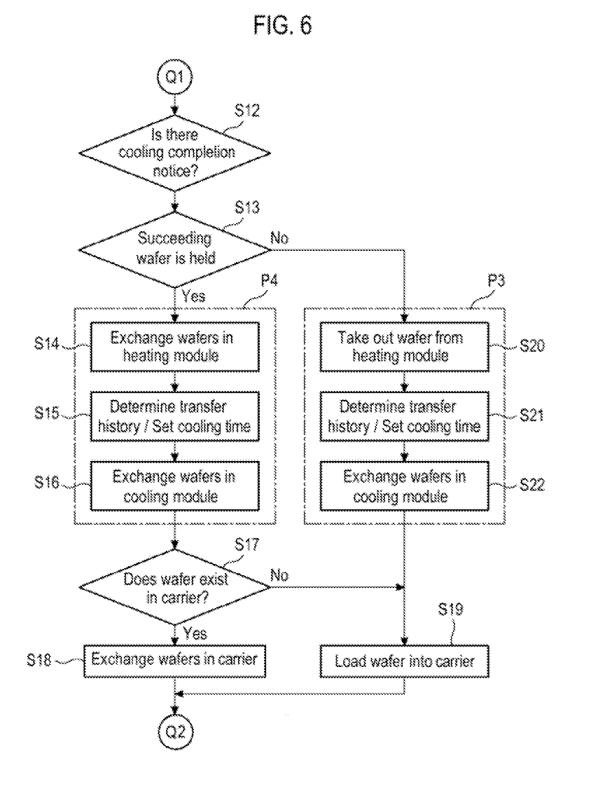

The term “exchange” refers to an operation of taking out a wafer W loaded in the heating module 4 or the cooling module 2 by one of the substrate holding members 30 (34 or 35), and continuously loading a wafer W held and supported by the other one of the substrate holding members 30 (34 or 35) into the heating module 4 or the cooling module 2, thereby exchanging a processed wafer W (e.g., after the processing) with an unprocessed wafer W (e.g., before the processing). Also, in a flowchart shown in FIGS. 5 and 6 described later, in addition to the heating module 4 and the cooling module 2, the term “exchange” is used in the operation of sending and receiving a wafer W to and from the carrier 9. The program storage part 62 is a computer storage medium, for example, a flexible disc, a compact disc, a hard disc, a magneto-optical disc, or the like in which the program is stored and installed in the control unit 6.

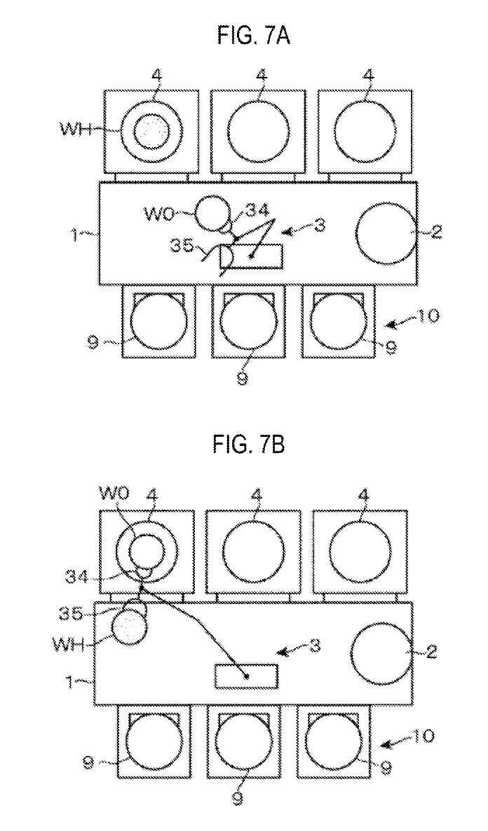

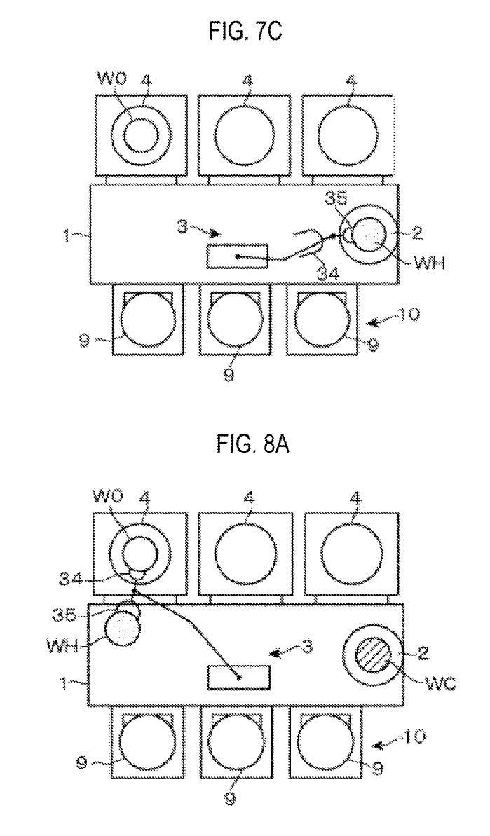

The operation of the substrate processing apparatus according to the embodiment of the present disclosure will be described with reference to the flowchart of FIGS. 5 and 6 and the views illustrating a first process of processing substrates of FIGS. 7A to 10B. An example of a process of processing substrates when the carrier 9 having, for example, 25 sheets of wafers W accommodated therein is transported is shown. For ease of understanding in the following description, a wafer W not subjected to the microwave heating processing is referred to as an unprocessed wafer WO, a wafer W subjected to the microwave heating processing is referred to as a wafer WH, and a wafer W subjected to the cooling processing is referred to as a wafer WC.

For example, when the carrier 9 having 25 sheets of wafers W is transported to the loading and unloading port 10, the first sheet of unprocessed wafer WO is initially taken out from the carrier 9 by the low temperature holding member 34 of the transfer arm 3, which is in the home position which is a standby position. In this step, if either of the heating modules 4 is in an empty state (“Yes,” at Step S1), the first sheet of the unprocessed wafer WO is loaded into the heating module 4 (Step S11). Since 24 sheets of unprocessed wafers WO are left in the carrier 9, the operation proceeds to Step S9 via Step S8 to take out the second sheet of unprocessed wafer WO from the carrier 9, and then, the transfer arm 3 returns to the home position and stands by (Step S10).

Additionally, since two of the heating modules 4 are in an empty state, the transfer arm 3 does not return to the home position but loads the unprocessed wafer WO into one of the heating modules 4, which are in an empty state. However, in order to avoid the complexity for illustrating it in the flowchart, the operation will be described on the assumption that the transfer arm 3 returns to the home position for convenience. Accordingly, the second and third sheets of unprocessed wafers WO in the carrier 9 are also loaded into the heating modules 4.

When the fourth sheet of unprocessed wafer WO is held and supported by the transfer arm 3, all heating modules 4 have an unprocessed wafer WO loaded therein (“No,” at Step S1), and the operation proceeds to Step S2. At this time, Steps S2 and S3 are repeated as the cooling module 2 is not used, and when a completion signal of the heating module 4 is output for the first sheet of unprocessed wafer WO (“Yes,” at Steps S2 and S3), the operation proceeds to Step S4. At Step S4 (“Succeeding wafer is held”), it is determined whether or not the succeeding unprocessed wafer WO is held and supported by the transfer arm 3, and if the transfer arm 3 holds and supports the succeeding unprocessed wafer WO as shown in FIG. 7A. Then, the operation proceeds to Step S5.

Then, as shown in FIG. 7B, the exchange operation between the unprocessed wafer WO and the wafer WH is performed at the heating module 4, and then, the wafer WH is directed to the cooling module 2 (FIG. 7C). Here, at Step S2 (“Heating completion notice”), it is determined whether or not there is a completion notice signal, which, for example, is output when a timer of managing the respective heating modules 4 goes off. The completion notice signal is output in anticipation of the time necessary for the transfer arm 3 to take out the wafer WH after the completion notice signal is output. Therefore, the wafer WH is taken out almost without a waiting time when the heating processing is completed.

Just before the wafer WH is loaded into the cooling module 2, a transfer history of the wafer WH is determined (Step S6). Since this wafer WH is the first wafer W, the wafer exchange is performed in the heating module 4 while the wafer exchange is not performed in the cooling module 2. For this reason, a transfer history for the first wafer is set to be the transfer history P2, in which the cooling time is 175 seconds, and as shown in FIG. 7C, the wafer WH is loaded into the cooling module and then cooled (Step S7). Thereafter, the transfer arm 3 takes out the fifth sheet of unprocessed wafer WO from the carrier 9 and stands by at the home position (Steps S8 to S10).

The fifth to seventh sheets of unprocessed wafers WO are then loaded into the heating modules 4 in sequence and subjected to the heating processing, and at the same time, the second to fourth sheets of wafers WH are sequentially taken out from the heating modules 4 and loaded into the cooling module 2.

Since the cooling stages 21 are formed in a four-stage manner, the second to fourth sheets of wafers WH are loaded into the cooling module 2 without performing the wafer W exchange operation at the cooling module 2. Therefore, the second to fourth sheets of wafers WH also have the transfer history P2, having the cooling time of 175 seconds similar to the first sheet of wafer WH.

In the meantime, for each of the first to fourth sheets of wafers WH, at a predetermined time before the completion of the cooling processing, a cooling completion notice signal is output from the cooling module 2, for example. This signal is output, for example, when the timer that is started when the wafer WH is loaded into the cooling stage 21 goes off This setting time of the timer is set to be somewhat shorter than the time necessary for cooling the wafer WH. That is, the program is designed so that the cooling time is set by adding a time period, during which the transfer arm 3 moves toward the heating module 4 to take out the next wafer WH and loads the wafer WH into the cooling module 2, to this setting time after the cooling completion notice signal is output. Therefore, when each wafer WC is unloaded from the cooling module 2, it is cooled by the cooling time set according to the transfer history of the wafer W.

When the eighth sheet of unprocessed wafer WO is being transferred to the heating module 4, the four sheets of the wafers WH have been already transferred to the cooling module 2 and the fifth to seventh sheets of unprocessed wafers WO are already transferred to the heating modules 4. That is, there is no empty cooling stage 21. For that reason, the operation proceeds to Step 51 and Step S2. When the heating processing of the preceding wafer W is completed prior to the completion of the cooling processing in the cooling module 2 (“No,” at Step S3), the operation proceeds to Step S12 in FIG. 6, waiting for the cooling processing in the cooling module 2 to be terminated.

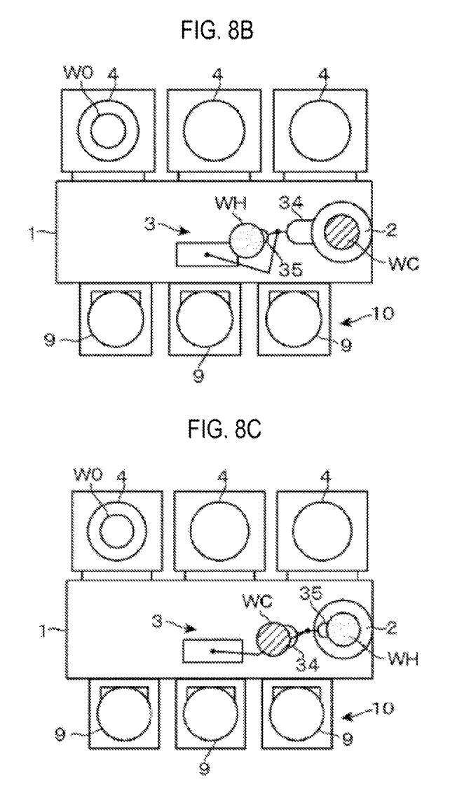

If the cooling completion notice signal is output, the eighth sheet of unprocessed wafer WO is loaded into the heating module 4 through the exchange operation in the heating module 4 as shown in FIG. 8A (Steps S13 and S14), and the preceding wafer WH is taken out from the heating module 4 and is directed to the cooling module 2 as shown in FIG. 8B. Then, the cooling time of the wafer WH is set according to its transfer history, and the wafer WH is loaded into the cooling module 2 as shown in FIG. 8C (Steps S15 and S16). Since this wafer WH has the transfer history P4 in which the exchange operation is performed in the cooling module 2 as well as the heating module 4, the cooling time is set to be, for example, 170 seconds. Since the unprocessed wafers W still remain in the carrier 9, the operation proceeds to Step S18 via Step S17 to return the wafer WC to the carrier and the transfer arm 3 takes out the ninth sheet of unprocessed wafer WO, and then, returns to the home position (Step S 10). The ninth to twenty-fourth sheets of unprocessed wafers WO are transferred to the heating modules 4 in the same process as the eighth sheet of unprocessed wafer WO.

The twenty-fifth sheet of unprocessed wafer WO is processed in the same steps as the process of loading the eighth sheet of unprocessed wafer WO into the heating module 4 until Step S16, but all the unprocessed wafers W have been already unloaded from the carrier 9. For this reason, the operation proceeds to “No” at Step S17, so that the transfer arm 3 loads the cooled wafer WC into the carrier (Step S19), and then, returns to the home position without holding and supporting an unprocessed wafer WO.

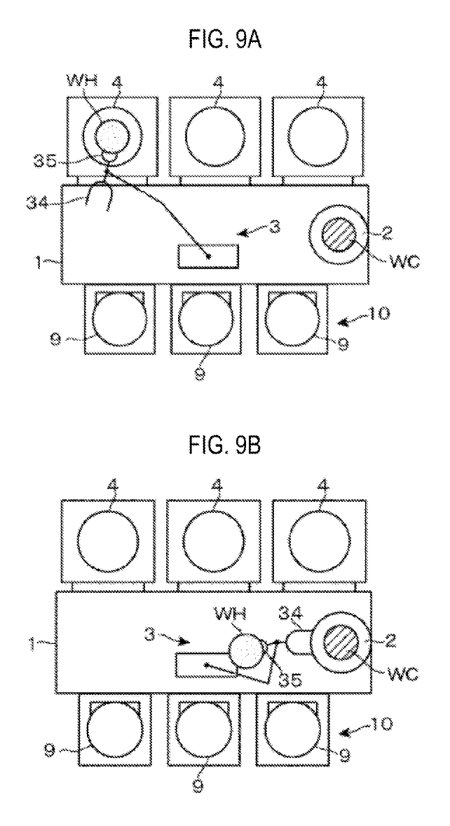

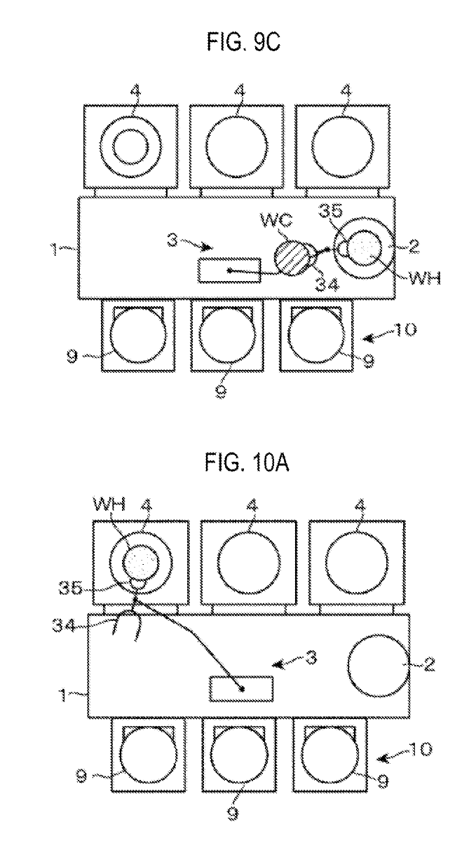

Thereafter, at Step S2 via Step S1, the operation waits for the heating processing to be terminated. If the completion of the heating of the twenty-third sheet of wafer W is expected, the operation proceeds to “No” at Step S3 via Step S2 to wait for the completion notice of the cooling module 2 (Step S12), and then, the flow proceeds to “No” at Step S13. Then, as shown in FIG. 9A, without exchanging the wafers W , the twenty-third sheet of wafer WH is taken out from the heating module 4 (Step S20) and transferred toward the cooling module 2 as shown in FIG. 9B, and the transfer history is determined (Step S21). Here, since the exchange operation is not performed in the heating module 4 and the exchange operation is performed in the cooling module 2, the transfer history of the twenty-third sheet of wafer WH is determined as P3, so that a cooling time of the twenty-third sheet of wafer WH set to be, for example, 175 seconds and it is cooled.

Also, although not shown in the flowchart, after the last wafers W in the respective heating modules 4, e.g., the twenty-third to twenty-fifth sheets of wafers WH, are transferred to the cooling module 2, the heating module 4 will be no longer in use. Accordingly, the determining whether the heating module 4 is empty is not performed at Step 51, the twenty-fourth and twenty-fifth sheets of wafers WH are transferred to the cooling module 2 in the same step as the twenty-third sheet of wafer WH.

After all the 25 sheets of wafers WH are transferred to the cooling module 2, the completion notice of the cooling processing is waited for at Step S23 via Steps 51 and S2. When all 25 processed wafers WC are unloaded from the cooling module 2 and returned to the carrier 9, the operation is terminated.

When not the completion notice signal of the heating processing but the completion notice signal of the cooling processing is generated, the operation proceeds to Step S2, Step S23, Step S24 and Step S25. That is, the cooled wafer WC is unloaded from the cooling module 2 and returned to the carrier 9.

In the above-described example, when the eighth to twenty-fifth sheets of unprocessed wafers WO are loaded into the heating modules 4, it is assumed that the wafers W are loaded in all the cooling stages 21. However, if the completely cooled wafers WC are returned to the carrier 9 continuously, the cooling module 2 may have an empty space when the eighth to twenty-fifth sheets of unprocessed wafers WO are transferred. In this case, the wafer W is transferred in the process when the fourth to seventh sheets of unprocessed wafers WO are transferred.

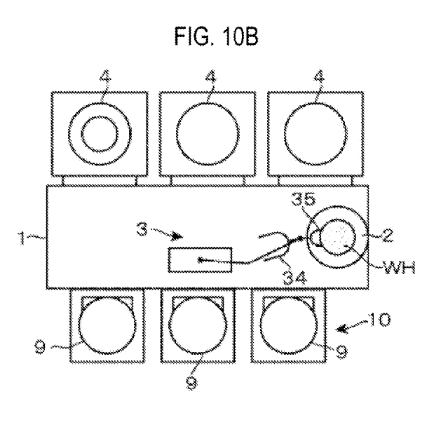

In addition, for example, depending on a relationship between the number of the wafers W transported by the carrier 9 and the respective numbers of the installed heating modules 4 and the installed cooling stages 21 of the cooling module 2, for example, when the number of the wafers W is equal to or less than that of any one of the heating modules 4 and the cooling stages 21 of the cooling module 2, it is assumed that all the unprocessed wafers WO are delivered to the heating modules and then the cooling module 2 has an empty space. In such a case, it is determined as “Yes” at Step S3 and “No” at Step S4. For that reason, as shown in FIG. 10A, the wafer WH is taken out from the heating module 4 (Step S26), and the cooling time of the wafer WH is set according to its transfer history (Step S27). Thereafter, as shown in FIG. 10B, the wafer WH is mounted to the cooling module 2 (Step S28). In this process, since the exchange operation is not performed in the heating modules 4 and the cooling module 2, the transfer history is determined to be P1 and the cooling time is set to be, for example, 180 seconds.

In addition, even in a case where the above-described twenty five sheets of wafers W are loaded, when the wafers WC of which the cooling processing is completed is continuously unloaded from the cooling module 2, it is assumed that the cooling module 2 has an empty space when all the unprocessed wafers WO are loaded into the heating modules 4, and then, the twenty-third to twenty-fifth sheets of wafers WH are transferred from the heating modules 4 to the cooling module 2. In that case, since the exchange operation is not performed in the heating modules 4 and the cooling module 2 in the same manner, the transfer history is determined to be P1 and the cooling time is set to be, for example, 180 seconds.

According to the above-described embodiment, the transfer history until the wafer W of which the heating processing is completed is transferred to the cooling module 2 is classified into four, i.e., P1 to P4, as already described above, and the cooling times are determined according to the respective transfer histories P1 to P4 (in this example, P2 and P3 are set to have the same cooling time). Therefore, when the transfer time from taking out a wafer W from the heating module 4 to loading it into the cooling module 2 is long, the wafer W has a large degree of heat radiation, and thus, the cooling time is adjusted to be short. In addition, when the transfer time is short, the cooling time is adjusted to be long. As a result, it is possible to prevent a wafer W from continuing to be excessively cooled after the wafer W is cooled to a target temperature, and the overall cooling time can be shortened to suppress the throughput deterioration.

In addition, the cooling times of the respective wafers W in the carrier 9 may be previously set by reading transfer schedules of the wafers W in advance just after the carrier 9 is loaded into the loading and unloading port 10.

Further, the cooling module 2 may include a cooling mechanism such as a chiller or the like. For example, a wafer W is mounted on a cooling stage, and water cooling tubing connected to a cooling mechanism including a chiller, a pump and the like is installed inside the cooling stage. After the wafer W of which the heating processing is completed is mounted on the cooling stage, the cooling mechanism may be cooled more by circulating cooling water in the water cooling tubing.

Although in the above-described example, a table with the transfer histories P1 to P4 associated with the cooling times is stored in the memory and the cooling times are read from the table, for example, the cooling time for the transfer histories P2 and P3 is set in advance and offset times for the transfer histories P1 to P4 may be set (an offset time for P2 and P3 is zero).

Also, in a relationship between the time necessary for the heating processing and the time necessary for the cooling processing, for example, when the wafer WH of which the heating processing is completed stands by in the heating module for a moment, in view of also this waiting time, a history from when the heating process of the wafer W is completed to when it is loaded into the cooling module 2 may be made as the transfer history. That is, a total time of the waiting time in the heating module and the transfer time by the transfer arm 3 is grasped as a transfer history, and the setting time may be determined according to the transfer history. In this case, a method such as of storing a table with the total time associated with the cooling time in the memory may be employed.

Also, although in the above-described example, the carrier 9 placed on the loading and unloading port 10 is equivalent to a substrate holding part, the substrate holding part may be a fixed shelf In addition, the transfer arm that transfers a wafer W from the substrate holding part to the heating module 4 and the cooling module 2 in order and the transfer arm that takes out a wafer W from the cooling module 2 and transfers it to the substrate holding part or another place may be separate from each other (for example, the whole joint arms may be separate from each other).

### Second Embodiment

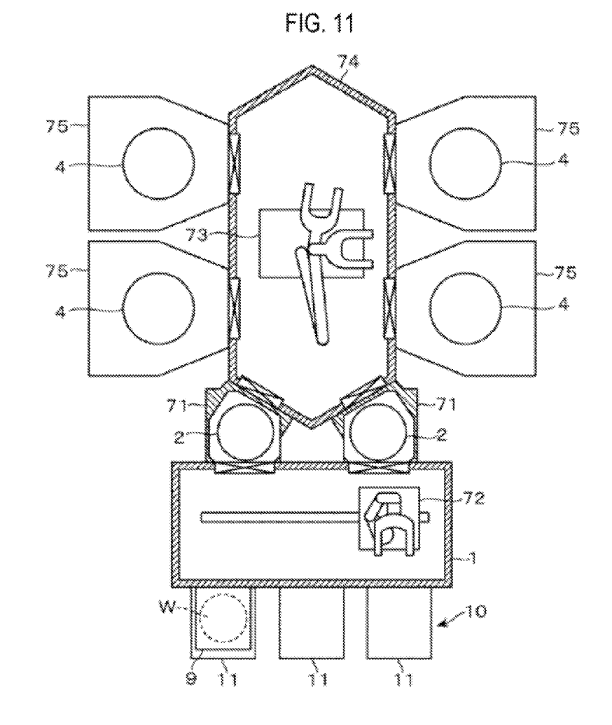

A substrate processing apparatus according to a second embodiment may be a vacuum processing apparatus as shown in FIG. 11. In the vacuum processing apparatus, a vacuum transfer chamber 74, for example, having a hexagonal plane shape, is connected to a side of an atmospheric transfer chamber 1 opposite to a loading and unloading port 10 through two load lock chambers 71 (preliminary vacuum chambers) disposed at the left and right sides. A first transfer arm 72 for sending and receiving a wafer W between the loading and unloading port 10 and the load lock chambers 71 is provided inside the atmospheric transfer chamber 1.

The interior of the vacuum transfer chamber 74 is maintained under vacuum atmosphere by mean of a vacuum pump (not shown), and four vacuum chambers 75, in each of which known processing atmosphere of a heating module 4 such as heater heating or microwave heating is formed, are connected to the vacuum transfer chamber 74. Also, the vacuum transfer chamber 74 is provided with a second transfer arm 73 capable of simultaneously holding and supporting a plurality of wafers W for sending and receiving the wafers W between the load lock chambers 71 and the heating modules 4. A cooling module 2 having a cooling stage 21, for example, is provided in each of the load lock chambers 71.

In this vacuum processing apparatus, the first transfer arm 72 takes out an unprocessed wafer W from a carrier 9 and loads the wafer W into the load lock chamber 71. The unprocessed wafer W passes through the load lock chamber 71, is held and supported by the second transfer arm 73 in the vacuum transfer chamber 74. The unprocessed wafer W is then loaded into each heating module. If the heating processing on a wafer W is already completed at that time, the wafer exchange is performed by taking out the wafer W of which the heating processing is completed and loading an unprocessed wafer W. In addition, the wafer W of which the heating processing is completed is loaded into the load lock chamber 71 and then mounted on the cooling stage 21 of the load lock chamber 71. On the other hand, the unprocessed wafer W which has been previously loaded in the load lock chamber 71 by the first transfer arm 72 is taken out from the load lock chamber 71, and the wafer W of which the heating processing is completed is mounted on the cooling stage 21. The wafer W of which the cooling processing is completed is returned to the carrier 9 by the first transfer arm 72.

In the substrate processing apparatus according to the second embodiment, in a case where a succeeding unprocessed wafer W is held and supported when the wafer W of which the heating processing is completed is taken out from the heating module 4, after the wafer W of which the heating processing is completed is taken out, the unprocessed wafer W is loaded into the heating processing module. Also, in a case where a succeeding unprocessed wafer W is mounted in the load lock chamber 71 when the wafer W of which the heating processing is completed is loaded into the load lock chamber 71, after the unprocessed wafer is taken out, the wafer W of which the heating processing is completed is mounted to the cooling stage 21 of the load lock chamber 71.

For that reason, depending on whether or not a succeeding wafer W is held and supported when a wafer W is taken out from the heating module 4 or whether or not a succeeding unprocessed wafer W is mounted in the load lock chamber 71 when the wafer W of which the heating processing is completed is loaded into the load lock chamber 71, a transfer time of the wafer W, on which the heating processing is completed, from the heating module 4 to the cooling stage 21 is changed. The same effects can be obtained by changing the cooling time of the wafer W of which the heating processing is completed according to these four transfer histories.

[Evaluation Test]

In order to evaluate the embodiments of the present disclosure, the substrate processing apparatus according to the first embodiment was used to perform the following evaluation test. After a wafer W was processed in the heating module 4 for 120 seconds, the wafer W was loaded into the cooling module 2 and cooled until the temperature of an edge of the wafer W was less than 80 degrees C. A case where the cooling processing is performed in the cooling module 2 without exchanging wafers W in each of the heating module 4 and the cooling module 2 is referred to as Reference Example 1, and a case where the cooling processing is performed in the cooling module with wafers W exchanged in each module is referred to as Reference Example 2.

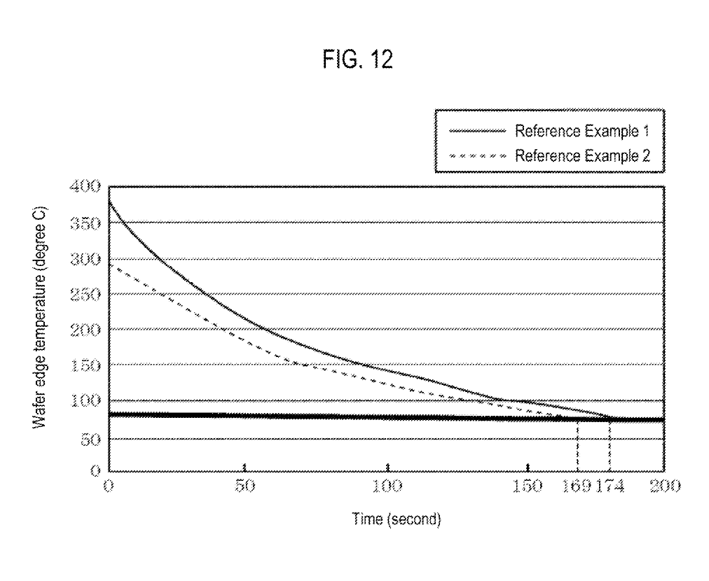

FIG. 12 is a characteristic diagram showing an aging change of the temperature at a wafer edge after initiating cooling a wafer W in the cooling module 2 according to Reference Examples 1 and 2. In Reference Example 1 where wafers W were not exchanged in the heating module 4 and the cooling module 2, the temperature of the edge of the wafer W when it was loaded into the cooling module 2 was a high temperature of 370 degrees C., and a time of 179 seconds was needed to cool the temperature to 80 degrees C. In the meantime, in Reference Example 2 where wafers W were exchanged in the heating module 4 and the cooling module 2, the temperature of the edge of the wafer W when it was loaded into the cooling module was fallen to a temperature of 290 degrees C., and a time of 169 seconds was needed to cool the temperature to 80 degrees C. When a wafer W was transferred in the process of Reference Example 2, the cooling time may be set to be shorter by 10 seconds than that of a case where a wafer W was transferred in the process of Reference Example 1. Therefore, since it is possible to reduce the overall cooling time by changing the cooling time based on the transfer process of a wafer W, it may be said that throughput deterioration can be suppressed.

According to the present disclosure, when a substrate after heating processing is cooled in the cooling module, a cooling time of the substrate is set based on a transfer history of the substrate from the heating module to the cooling module. Therefore, it is possible to prevent a substrate from continuing to be excessively cooled after the temperature of the substrate is decreased until the temperature reaches a target temperature, and accordingly, it is possible to suppress throughput deterioration since the substrate can be rapidly taken out from the cooling module.

While certain embodiments have been described, these embodiments have been presented by way of example only, and are not intended to limit the scope of the disclosures. Indeed, the novel methods and apparatuses described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus, comprising
a substrate holding part configured to hold and support a substrate;
a heating module configured to heat a substrate;
a cooling module configured to cool the substrate heated in the heating module;
a substrate transfer mechanism configured to take out the substrate from the substrate holding part and to sequentially transfer the substrate to the heating module and to the cooling module; and
a control unit configured to set a cooling time of the substrate in the cooling module based on a transfer history of the substrate while the substrate heated in the heating module is loaded into the cooling module.

2. The substrate processing apparatus of claim 1, wherein the substrate transfer mechanism comprises a first holding member and a second holding member configured to be independently extended and retracted to exchange substrates and to respectively hold and support the substrates.

3. The substrate processing apparatus of claim 2, wherein the substrate transfer mechanism is configured to take out the cooled substrate from the cooling module.

4. The substrate processing apparatus of claim 3, wherein the substrate holding part is a transfer container configured to accommodate a plurality of substrates mounted in a container mounting part, and the substrate transfer mechanism is configured to deliver the substrate taken out from the cooling module to the transfer container.

5. The substrate processing apparatus of claim 2, wherein the transfer history is the number of times the substrate is delivered by one of the first and second holding members after the substrate is taken out from the heating module by the other holding member.

6. A method of processing a substrate, comprising:
loading a substrate from a substrate holding part to a heating module by a substrate transfer mechanism;
unloading the heated substrate from the heating module and loading it to a cooling module by the substrate transfer mechanism;
setting a cooling time of the substrate in the cooling module based on a transfer history of the substrate while the substrate heated in the heating module is loaded into the cooling module; and
unloading the substrate from the cooling module after the cooling time elapses in the cooling module.

7. The method of claim 6, wherein the substrate transfer mechanism comprises a first holding member and a second holding member configured to be independently extended and retracted to exchange substrates and respectively hold and support the substrates.

8. The method of claim 7, wherein the unloading the substrate from the cooling module is performed by the substrate transfer mechanism.

9. The method of claim 8, wherein the substrate holding part is a transfer container configured to accommodate a plurality of substrates mounted in a container mounting part, and the substrate transfer mechanism is controlled to deliver the substrate taken out from the cooling module to the transfer container.

10. The method of claim 7, wherein the transfer history is the number of times the substrate is delivered by one of the first and second holding members after the substrate is taken out from the heating module by the other holding member.

11. A non-transitory storage medium storing a computer program used in a substrate processing apparatus including a heating module configured to heat a substrate, a cooling module configured to cool a substrate, and a substrate transfer mechanism,
wherein the computer program includes a group of steps for performing the method according to claim 6.
